(19) United States
(12) Patent Application Publication
(10) Pub. No.: US 2025/0357940 A1
(43) Pub. Date: Nov. 20, 2025

(54) OFFSET CORRECTION AND/OR REFERENCE CALIBRATION FOR CONVERSION CIRCUITRY

(71) Applicant: TEXAS INSTRUMENTS INCORPORATED, DALLAS, TX (US)

(72) Inventors: Varun UPADHYAYA, NEW DELHI (IN); Alark FAJALIA, VADODARA (IN); Nitin AGARWAL, BANGALORE (IN)

(21) Appl. No.: 18/954,713

(22) Filed: Nov. 21, 2024

(30) Foreign Application Priority Data
May 17, 2024 (IN) 202441038818

(51) Int. Cl. H03M 1/06

(52) U.S. Cl. CPC H03M 1/0607

(57) ABSTRACT

In a described example, a circuit includes a comparator circuit including an input, a first output, and a second output. An offset control circuit includes a first input, a second input, a first output, and a second output, in which the first input is coupled to the first output of the comparator circuit, the second input is coupled to the second output of the comparator circuit. A first delay circuit is coupled between the first input and the first output of the offset control circuit. A second delay circuit is coupled between the second input and the second output of the offset control circuit. An offset calibration circuit has a first input and a second input, in which the first input is coupled to the first output of the offset control circuit, the second input is coupled to the second output of the offset control circuit.

### RELATED APPLICATION

This application claims priority from Indian Provisional Patent Application Serial No. 202441038818, filed May 17, 2024, which Application is hereby incorporated herein by reference in its entirety.

### TECHNICAL FIELD

This description relates to offset correction and/or reference calibration for conversion circuitry.

### BACKGROUND

Analog-to-digital converters (ADCs) are used in a variety of applications to convert analog signals into digital signals. In ADCs that include low offset comparators can be used, the offset can sometimes be corrected by trim methods. However, the trimming cannot compensate for all offset (e.g., for drift in offset due to temperature change), and additional offset cancellation methods may be implemented to improve performance.

### SUMMARY

One described example relates to a circuit that includes a comparator circuit including an input, a first output, and a second output. An offset control circuit includes a first input, a second input, a first output, and a second output, in which the first input is coupled to the first output of the comparator circuit, the second input is coupled to the second output of the comparator circuit. A first delay circuit is coupled between the first input and the first output of the offset control circuit. A second delay circuit is coupled between the second input and the second output of the offset control circuit. An offset calibration circuit has a first input and a second input, in which the first input is coupled to the first output of the offset control circuit, the second input is coupled to the second output of the offset control circuit. A capacitor can be coupled to the input of the comparator circuit.

Another example circuit includes a buffer including an output. An analog-to-digital converter includes an input and an output. A leakage cancellation circuit is coupled between the output of the buffer and the input of the analog-to-digital converter. The leakage cancellation circuit is configured to simulate leakage error of a digital-to-analog converter circuit, and the analog-to-digital converter is configured to provide calibration data at the output of the analog-to-digital converter based on the simulated leakage error.

Another described example relates to an analog-to-digital converter system. The analog-to-digital converter system includes a comparator circuit configured to provide first and second comparator output signals based on receiving first and second input signals and an offset signal. The analog-to-digital converter system also includes an offset correction circuit that includes an offset control circuit and an offset calibration circuit. The offset control circuit is configured to provide calibration control signals responsive to the first and second comparator output signals and a calibration timing signal. The offset calibration circuit includes a charge pump and is configured to provide the offset signal responsive to the calibration control signals, in which the calibration control signals are provided to control a net charge of the offset signal during pull-up and pull-down phases of the charge pump.

### BRIEF DESCRIPTION OF THE DRAWINGS

FIG. 1 is a block diagram of an example analog-to-digital converter circuit.

FIG. 2 is a block diagram of part of an analog-to-digital converter circuit depicting an example offset correction circuit.

FIG. 3 is a block diagram of an example offset control circuit.

FIG. 4 is a diagram of an example monoshot circuit that can be implemented in the offset control circuit of FIG. 3.

FIG. 5 is a diagram of an example delay circuit that can be implemented in the offset control circuit of FIG. 3.

FIG. 6 is a signal diagram depicting examples of timing signals for various parts of an offset correction circuit.

FIG. 7 is a signal diagram depicting an example of convergence for an offset signal of an offset correction circuit.

FIG. 8A is a signal diagram depicting examples of switch control signals that can be provided by an offset control circuit.

FIG. 8B is a circuit diagram depicting part of an example offset calibration circuit for use in describing the signal diagram of FIG. 8A.

FIG. 9 is a circuit diagram of an example reference calibration circuit.

FIG. 10 is a circuit diagram of an example of part of an analog-to-digital converter circuit depicting an example reference calibration circuit.

FIG. 11 is a circuit diagram of an example reference buffer circuit.

FIG. 12 is a block diagram depicting an example control loop analog-to-digital converter.

FIG. 13 is a circuit diagram of an example capacitive digital-to-analog converter that can be implemented in the control loop analog-to-digital converter of FIG. 12.

FIG. 14 is a block diagram of an example system that includes an analog-to-digital converter.

### DETAILED DESCRIPTION

This description relates to circuitry to implement reference calibration and/or offset correction for conversion circuitry, such as for analog-to-digital converters (ADCs).

As an example, conversion circuitry, such as an ADC, includes a comparator circuit, an offset correction circuit, and an offset calibration circuit. The comparator circuit is configured to provide a comparator output signal based on one or more input signals and an offset signal. The offset correction circuit includes an offset control circuit and an offset calibration circuit. The offset control circuit is configured to provide a calibration control signal responsive to the comparator output signal and a calibration timing signal. The offset calibration circuit includes a charge pump configured to provide the offset signal at an offset input of the comparator circuit responsive to the calibration control signal. The calibration control signal is adapted to control a net charge at the offset input during operation of the charge pump, such that intended sequencing of the comparator circuit is ensured. As a result, finer offset calibration can be implemented and/or an overall reduction in the on-die area of the conversion circuit can be achieved compared to many existing approaches.

As an additional or alternative example, the conversion circuitry includes a reference buffer, a leakage cancellation circuit, and a calibration analog-to-digital converter. The reference buffer is configured to provide a reference signal for the conversion circuitry. The leakage cancellation circuit is configured to simulate a leakage error of a digital-to-analog converter circuit of the analog-to-digital converter system and provide an adjusted reference signal. The calibration analog-to-digital converter is configured to provide calibration data based on the adjusted reference signal. Because the calibration data is derived from the adjusted reference signal, which accounts for the leakage errors, such leakage errors can be calibrated out by downstream circuitry.

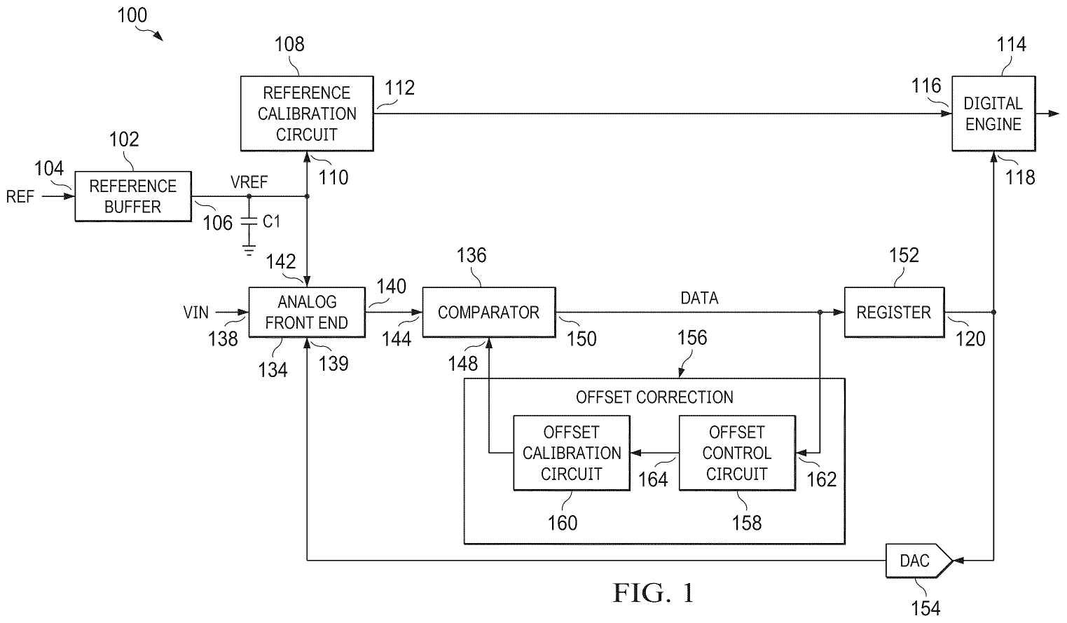

FIG. 1 is a block diagram of an example ADC circuit 100. The ADC circuit 100 can be implemented on an IC chip, and the IC chip can include one or more instances of the ADC circuit 100. As an example, the IC chip is a controller for a power converter, such as a multi-phase DC to DC power converter. One or more instances of the ADC circuit 100 can be implemented in ICs for a variety of other purposes. The ADC circuit 100 can be fabricated on a die with a reduced area compared to existing ADCs leading to a reduced area for the die. The ADC circuit can also exhibit improved performance compared to many existing ADC circuits.

The ADC circuit 100 includes a reference buffer 102 including a reference input 104 and a reference output 106. A capacitor C1 can be coupled between the reference output 106 and a ground terminal. While one reference output 106 is shown in FIG. 1, there can be a pair of reference outputs in other examples. The reference buffer 102 is configured to provide a reference signal VREF at the reference output 106 based on an input reference signal REF. As described herein, the reference signal VREF can be provided to various parts of the ADC circuit 100.

In the example of FIG. 1, the ADC circuit 100 includes a reference calibration circuit 108 including an input 110 and an output 112, in which the input 110 is coupled to the reference output 106. The reference calibration circuit 108 is configured to simulate (or recreate) leakage error of a digital-to-analog converter circuit and provide calibration data at the output 112 based on the simulated leakage error, in which the switch leakage errors are calibrated out of the calibration data. A digital engine 114 includes an input 116 coupled to the output 112 and another input 118 which can be coupled to an output 120 of the ADC circuit 100. The digital engine 114 can be configured to correct a digital output signal of the ADC circuit 100 received at the input 118 based on the calibration data received at the input 116. The digital engine further can be configured to generate sampling, clocking and other control signals used in the ADC circuit 100 (e.g., used by the analog front end and comparators), which depends on the architecture of the ADC circuit.

The ADC circuit 100 includes an analog front end circuit (e.g., a successive approximation (SAR) analog front end) 134 and a comparator circuit (e.g., a SAR comparator circuit) 136. The analog front end circuit 134 includes one or more front-end inputs 138, a feedback input 139, one or more front-end outputs 140, and a voltage input 142, in which the voltage input 142 is coupled to the reference output 106 to receive the reference signal VREF. The one or more front-end inputs 138 can be coupled to ADC input terminals, which can receive a respective analog input signal VIN, which is to be converted to respective digital version thereof by the ADC circuit 100. The one or more front-end outputs 140 are coupled to one or more respective inputs of the comparator circuit 136. In an example, the analog front end circuit 134 includes an arrangement of capacitors and switches (e.g., transistors) between respective inputs and outputs 138 and 140. The analog front end circuit 134 can be configured to implement sample and hold functions and to provide an analog input signal (e.g., as a differential input signal) at the one or more front-end outputs 140 based on the one or more input signals VIN at the respective one or more inputs 138, a feedback signal received at the feedback input 139, and the reference signal VREF at the voltage input 142.

The comparator circuit 136 includes one or more signal inputs 144, an offset input 148, and one or more comparator outputs 150. For example, the comparator circuit 136 includes a strong-arm latch circuit configured to implement comparator functions. The one or more signal inputs 144 are coupled to the one or more outputs 140. A register 152 has an input coupled to the one or more comparator outputs 150 and an output of the register is coupled to or constitutes the output 120 of the ADC circuit 100. The comparator circuit 136 is configured to provide a data signal (DATA) at the one or more outputs 150 based on the signal signal(s) at the one or more inputs 144 (provided by the analog front end circuit 134), an offset signal at the offset input 148, and a clock signal (not shown). The DATA signal can be a stream of bits, and the register can be configured to store the bits to provide a multi-bit digital output at the output 120. A digital-to-analog converter (DAC) 154 is coupled between the output 120 and the feedback input 139 of the analog front end circuit 134. The DAC 154 can be configured to convert the digital signal at the output 120 to a respective analog signal representative of the input digital signal.

The ADC circuit 100 also includes an offset correction circuit 156 coupled between the one or more comparator outputs 150 and the offset input 148 of the comparator circuit 136. The offset correction circuit 156 includes an offset control circuit 158 and an offset calibration circuit 160. The offset correction circuit 156 can operate as a background calibration loop to reduce the offset of the comparator circuit 136 that can vary across temperature. The offset control circuit 158 includes one or more inputs 162 and one or more offset outputs 164, in which the one or more inputs are coupled to the one or more comparator outputs 150. The offset control circuit 158 is configured to provide one or more calibration control signals at the one or more offset outputs 164 responsive to the comparator output signal DATA provided (e.g., by the comparator circuit 136) at the one or more comparator outputs 150. As described herein, the offset control circuit 158 is configured to control the timing (e.g., for turning on and off switches) of offset calibration circuit 160 to ensure loop convergence so the offset calibration circuit can reduce or cancel offset can occur at the comparator circuit 136. The offset correction circuit 156 provides a useful approach to implement offset correction when autozeroing is not feasible due to the fast sampling rates (e.g., 50 MSPS, 100 MSPS, or greater) of the comparator circuit 136. The offset correction can implement finer offset calibration and/or achieve an overall reduction in the on-die area of the conversion circuit compared to many existing approaches.

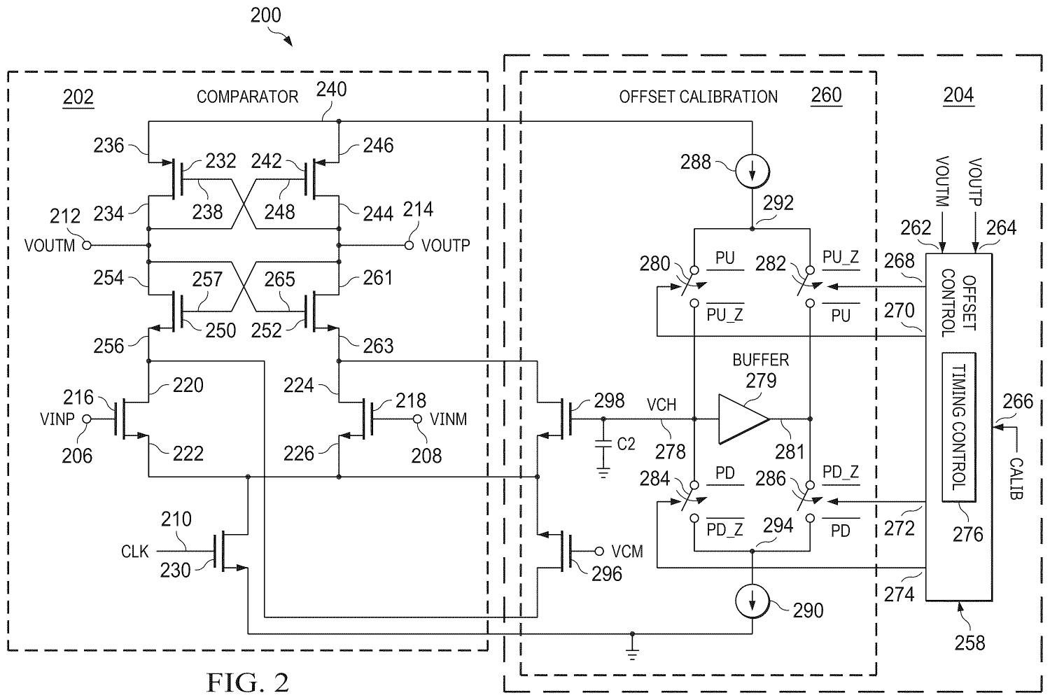

FIG. 2 is a block diagram of part of an ADC circuit 200 depicting a comparator circuit 202 and an offset correction circuit 204. The comparator circuit 202 is a useful example of the comparator circuit 136 and the offset correction circuit 204 is a useful example of the offset correction circuit 156. Accordingly, the description of FIG. 2 may refer to certain aspects of FIG. 1. Other configurations of the comparator circuit can be used in other examples.

In the example of FIG. 2, the comparator circuit 202 includes voltage inputs 206 and 208, a clock input 210, and comparator outputs 212 and 214. The comparator circuit 202 can be a differential comparator. For example, the comparator circuit 202 is configured to compare voltage signals VINP and VINM received at respective voltage inputs 206 and 208 (e.g., from the analog front end circuit 134) and provide comparator output signals VOUTM and VOUTP at respective comparator outputs 212 and 214. The comparator circuit 202 can provide the comparator output signals VOUTM and VOUTP as complementary signals based on the comparison of the voltage signals VINP and VINM. A cycle time for each compare cycle of the comparator circuit 202 is defined by a clock signal (CLK) received at the clock input 210.

For example, the comparator circuit 202 includes transistors (e.g., n-channel field effect transistors (FETs)) 216 and 218. The transistor 216 has a first current input (e.g., drain) 220, a second current input (e.g., a source) 222, and a control input (e.g., gate), in which the control input is coupled to the voltage input 206 to receive the input voltage signal VINP. The transistor 218 has a first current input (e.g., drain) 224, a second current input (e.g., a source) 226, and a control input (e.g., gate), in which the control input is coupled to the voltage input 208 to receive the input voltage signal VINM. Each of the second current inputs 222 and 226 are coupled together (e.g., at a common node), and a transistor (e.g., n-channel FET) 230 is coupled between the second current inputs 222 and 226 and a ground terminal. The transistor 230 has a control input coupled to the clock input 210.

The comparator circuit 202 includes a transistor (e.g., a p-channel FET) 232 having a first current input (e.g., drain) 234, a second current input (e.g., source) 236, and a control input (e.g., gate) 238, in which the first current input 234 is coupled to the comparator output 212 and the second current input 236 is coupled to a voltage supply terminal 240. The voltage supply terminal 240 can be coupled to the output of a voltage regulator to receive a regulated voltage, which can vary depending on application requirements. Another transistor (e.g., p-channel FET) 242 has a first current input (e.g., drain) 244, a second current input (e.g., source) 246, and a control input (e.g., gate) 248, in which the first current input 244 is coupled to the comparator output 214 and the second current input 246 is coupled to the voltage supply terminal 240. Also, the control input 238 of the transistor 232 is coupled to the comparator output 214 and the control input of transistor 242 is coupled to the comparator output 212. The transistors 232 and 242 can thus define a cross-coupled pair of transistors.

The comparator circuit 202 also includes another cross-coupled pair of transistors 250 and 252. The transistor (e.g., an n-channel FET) 250 has a first current input (e.g., drain) 254, a second current input (e.g., source) 256, and a control input (e.g., gate) 257, in which the first current input 254 is coupled to the comparator output 212, the second current input 256 is coupled to the first current input 220 of the transistor 216, and the control input 257 is coupled to the comparator output 214. The transistor 252 (e.g., an n-channel FET) has a first current input (e.g., drain) 261, a second current input (e.g., source) 263, and a control input (e.g., gate) 265, in which the first current input 261 is coupled to the comparator output 214, the second current input 263 is coupled to the first current input 224 of the transistor 218, and the control input 265 is coupled to the comparator output 212. Thus, each of the transistors 232 and 250 can have respective control inputs (e.g., gates) coupled together and the transistors 242 and 252 can have respective control inputs (e.g., gates) coupled together. The transistors 216, 218, 232, 242, 250, and 252 can define a strong arm latch circuit that constitutes the core of the comparator circuit 202. The strong-arm latch circuit can operate with a single clock phase at the clock input 210, draw little or no static power, and deliver rail to rail output swings at the comparator outputs 212 and 214 responsive to the inputs at 206 and 208.

As an example, input voltages VINP and VINM are received at respective voltage inputs 206 and 208, which can be provided by an analog front end circuit (e.g., analog front end circuit 134). The comparator circuit 202 also receives a clock signal CLK at clock input 210. The clock signal CLK can be provided by a clock generator (e.g., an oscillator, or other clock generator circuitry). In the example of FIG. 2, the comparator circuit 202 is shown as including a strong-arm latch circuit, in which the transistors 216 and 218 define a clocked differential pair. The transistors 250 and 252 and transistors 232 and 242 define respective cross-coupled pairs. Other types of comparator circuits can be used in other examples. The comparator circuit 202 is configured to provide comparator output signals VOUTM and VOUTP at respective comparator outputs 212 and 214 based on the relative input voltages VINP and VINM and responsive to the clock signal CLK. As described herein, each of the comparator output signals VOUT1 and VOUT2 can define output data having a binary value that can vary (e.g., approximating VDD or ground) based on the input voltages VINP and VINM with each cycle of the clock signal CLK. In some examples, one of the comparator output signals VOUT1 and VOUT2 is used as the DATA output of the ADC circuit and the other signal can be disregarded (or discarded).

The offset correction circuit 204 includes an offset control circuit 258 (e.g., the offset control circuit 158) and an offset calibration circuit 260 (e.g., the offset calibration circuit 160). The offset control circuit 258 includes inputs 262, 264, and 266 and outputs 268, 270, 272, and 274. The inputs 262 and 264 are coupled to the comparator outputs 212 and 214 to receive the comparator output signals VOUTM and VOUTP. The input 266 can receive a calibration timing signal, shown as CALIB. For example, the calibration timing signal CALIB can be a signal to control activation of the offset correction circuit 204, such as a periodic signal to implement calibration periodically in a background process. The offset control circuit 258 also includes a timing control circuit 276, which can be coupled between one or more of the inputs 262 and 264 and a respective set of the outputs 268, 270, 272, and 274.

The offset calibration circuit 260 is coupled between the voltage supply terminal 240 and the ground terminal. The offset calibration circuit 260 includes control inputs, each of which is coupled to a respective one of the outputs 268, 270, 272, and 274. The offset calibration circuit 260 also includes an output (e.g., also referred to as an offset output or calibration output) 278 coupled to an offset input of the comparator circuit 202 and a buffer 279 having an input coupled to the output 278. A capacitor C2 is coupled between the output 278 (also the offset input) and the ground terminal. In the example of FIG. 2, the offset calibration circuit 260 includes pull-up switches 280 and 282, in which the pull-up switch 280 is coupled between the voltage supply terminal 240 and the offset output 278 and the pull-up switch 282 is coupled between the voltage supply terminal 240 and an output 281 of the buffer 279. The pull-up 280 has a control input coupled to the output 270 and the pull-up switch 282 has a control input coupled to the output 268. The offset calibration circuit 260 also includes pull-down switches 284 and 286, in which the pull-down switch 284 is coupled between the offset output 278 and the ground terminal, and the pull-down switch 286 is coupled between the output 281 of the buffer 279 and the ground terminal. A voltage, shown as VCH, is provided at the output 278 across the capacitor C2 responsive to operation of switches 280, 282, 284, and 286 of the offset calibration circuit 260, which is controlled by the offset control circuit 258 as described herein. By controlling the switches 280, 282, 284, and 286 of the offset calibration circuit 260, as described herein, clock feedthrough cancellation is improved such that the circuit can use a smaller capacitor C2 in the charge pump implemented by the offset calibration circuit 260 compared to many existing approaches.

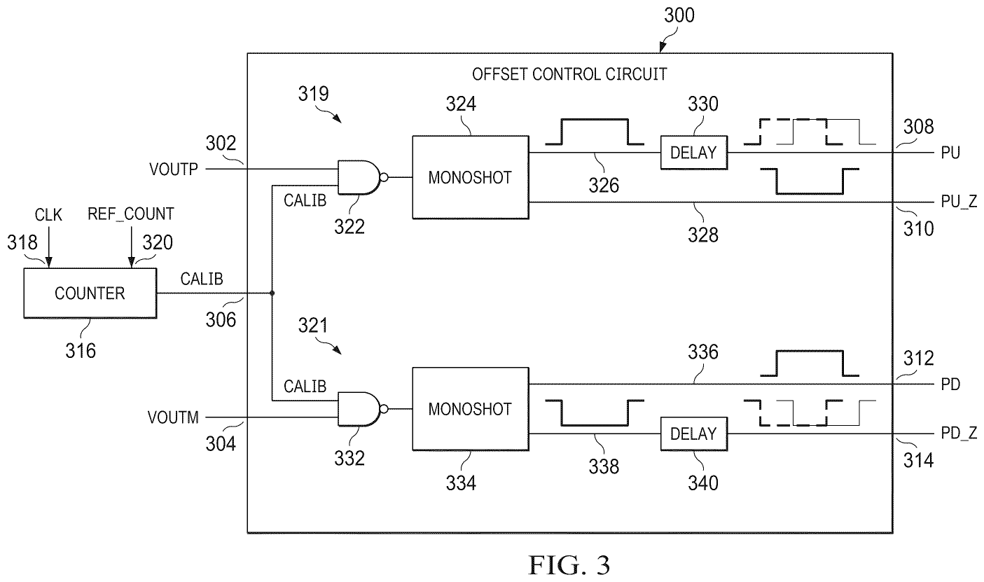

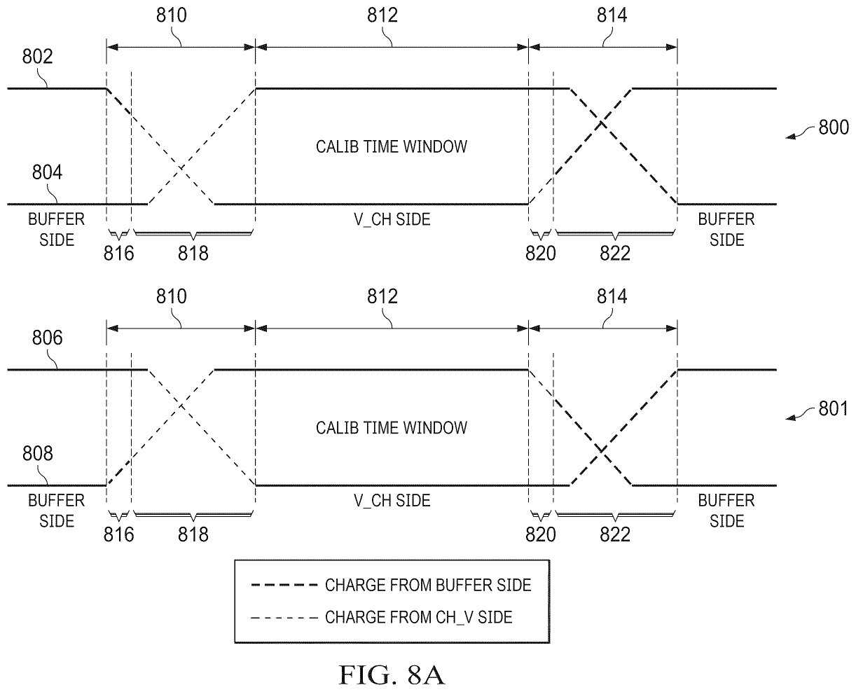

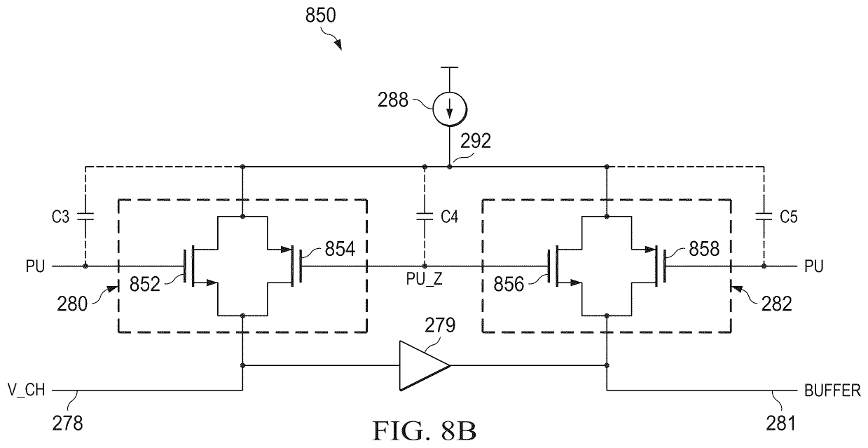

The timing control circuit 276 is configured to control a relative timing of the control signals (e.g., logic signals having either an on or off state) provided at the outputs 268, 270, 272, and 274 of the offset control circuit 258 to control the respective switches 280, 282, 284, and 286. In an example, the timing control circuit 276 is configured to control relative timing of rising or falling edges of the signals at the outputs 268 and 270 as well as control relative timing of rising or falling edges of the signals at the outputs 272 and 274. As described herein (see, e.g., FIGS. 3 and 8) the timing control circuit 276 can be configured to delay one of the signals at the outputs 268 and 270 to the pull-up switches 280 or 282 and delay one of the signals at the outputs 272 and 274 to the pull-down switches 284 or 286 to enforce a desired relative timing of the respective pull-up and pull-down switches.

The offset calibration circuit 260 also includes current sources 288 and 290. The current source 288 is coupled between the voltage supply terminal 240 and a common node terminal 292 of the switches 280 and 282. The common node terminal 292 defines a sensitive node that affects operation of the offset calibration circuit 260. The other current source 290 is coupled between a common node terminal 294 of the switches 284 and 286 and the ground terminal. In the example of FIG. 2, the current source 288 is configured to source current for the offset calibration circuit 260 and the current source 290 is configured to sink current for the offset calibration circuit 260, which charges and discharges the capacitor C2 to provide the voltage VCH at the offset output 278 based on the offset control signals provided at the outputs 268, 270, 272, and 274. In some examples, responsive to detecting that the offset voltage VCH converges to a desired calibration voltage, the offset control circuit 258 (or another circuit) can deactivate one or both of the current sources 288 and 290, which can reduce power consumption. In other examples, the current sources 288 and 290 may be omitted from the offset calibration circuit 260, in which case the common node terminal 292 can be coupled directly to the voltage supply terminal 240 and the common node terminal 294 can be coupled directly to the ground terminal.

The offset calibration circuit 260 also includes transistors 296 and 298, which define auxiliary transistors coupled across the respective transistors 216 and 218. The transistor 296 (e.g., an n-channel FET) includes a first current input (e.g., drain), a second current input (e.g., source), and a control input (e.g., gate), in which the first current input is coupled to the first current input of the transistor 216 and the second current input is coupled to the second current input of the transistor 216. The transistor 298 (e.g., an n-channel FET) includes a first current input (e.g., drain), a second current input (e.g., source), and a control input (e.g., gate), in which the first current input is coupled to the first current input of the transistor 218 and the second current input is coupled to the second current input of the transistor 218. The control input of the transistor 296 is coupled to a common mode voltage terminal to receive the common mode voltage VCM. The control input of the transistor 298 is coupled to the output 278 of the offset calibration circuit 260 to receive the offset signal, which is shown as charge pump voltage VCH.

The offset calibration circuit 260 thus constitutes a charge pump configured to provide the offset signal at the offset output 278, which is coupled to the control input (e.g., gate) of the transistor 296, responsive to the calibration control signals provided (e.g., by the offset control circuit 258) at the outputs 268, 270, 272, and 274. The offset control circuit 258 is configured to provide the calibration control signals at the outputs 268, 270, 272, and 274 to control a net charge at the offset output 278 across the capacitor C2 during respective pull-up and pull-down phases of the charge pump. For examples, the offset control circuit 258 is configured to delay the control signal at one of the outputs 268 or 270 to respective pull-up switch 282 or 280, respectively, and the control signal at one of the outputs 272 or 274 to respective pull-up switch 286 or 284, respectively. As a result of ensuring feedthrough effect is in the same direction as intended by sinking/sourcing current across C2, a smaller capacitor C2 can be used in the offset calibration circuit 260 compared to many existing approaches.

FIG. 3 is a block diagram of example offset control circuit 300. The offset control circuit 300 is a useful example of the offset control circuit 158 and 258, such that the description of FIG. 3 can refer to certain aspects of FIGS. 1 and 2. The offset control circuit 300 includes inputs 302, 304, and 306, and outputs 308, 310, 312, and 314. The inputs 302 and 304 can be coupled to respective outputs of a comparator circuit (e.g., outputs of comparator circuit 136, 202). In the example of FIG. 3, the input 306 is coupled to an output of a counter circuit 316. The counter circuit 316 includes inputs 318 and 320, in which the input 318 is coupled to an output of a clock circuit to receive a clock signal (CLK) and the input 320 receives a reference count value (REF_COUNT). The reference count value REF_COUNT can be defined to set the frequency of a calibration signal CALIB (e.g., the CALIB signal received at the input 266 of FIG. 2). While the counter circuit 316 is shown as being external to the offset control circuit 300, in other examples, the counter circuit 316 can be implemented as part of the offset control circuit. For example, the CLK signal at the input 318 is also used to clock the comparator circuit (e.g., comparator circuit 136, 202) that provides output signals received at the inputs 302 and 304. The counter circuit 316 can be configured to provide the calibration signal CALIB based on the clock signal and the reference count value to trigger the offset control circuit periodically. The offset control circuit 300 can be configured to provide respective control signals at the outputs 308, 310, 312, and 314 responsive to the comparator output signals at the inputs 302 and 304 and the calibration signal CALIB at the input 306. In an example, the counter circuit 316 is configured to provide calibration signal CALIB to activate the offset control circuit 300 once for each compare cycle, which can depend on the number of bits defined for each compare cycle.

In the example of FIG. 3, the offset control circuit 300 includes a pull-up control path 319 and a pull-down control path 321. The pull-up control path 319 includes logic (e.g., a NAND gate) 322 having inputs coupled to the input 302 (e.g., comparator output 214) and the input 306 (e.g., output of the counter circuit 316). A monoshot circuit (e.g., pulse generator circuit) 324 has an input coupled to the output of the logic 322 and outputs 326 and 328. For example, the signals at 326 and 328 can be inverted (e.g., complementary) versions of each other. A delay circuit 330 is coupled between the output 326 of the monoshot circuit 324 and the output 308, and the output 328 can be coupled directly to the output 310. For example, the logic 322 is configured to logically AND the comparator output VOUTP and the calibration signal CALIB and provide a logic output signal to the monoshot circuit 324. The monoshot circuit is configured to provide complementary pulse signals at the respective outputs 326 and 328. The delay circuit 330 is configured to delay the pulse signal at the output 326 to provide a delayed version thereof at the output 308. For example, the rising edge of the control signal at the output 308 is delayed relative to the falling edge of the control signal at the output 310.

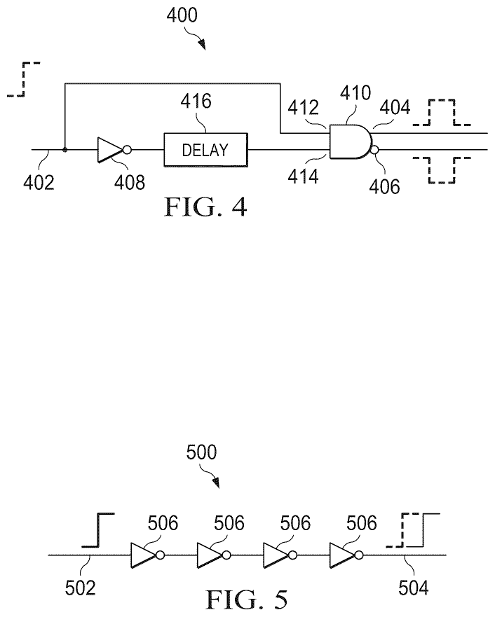

The pull-down control path 321 includes logic (e.g., a NAND gate) 332 having inputs coupled to the input 304 (e.g., comparator output 212) and the input 306 (e.g., output of the counter circuit 316). A monoshot circuit (e.g., pulse generator circuit) 334 has an input and outputs 336 and 338, in which the input thereof is coupled to the output of the logic 332. The output 336 is coupled directly to the output 312, and a delay circuit 340 is coupled between the output 338 of the monoshot circuit 324 and the output 314. The delay circuits 330 and 340 can, individually or collectively define a timing control circuit (e.g., the timing control circuit 276). For example, the logic 332 (e.g., a NAND gate) is configured to logically AND the comparator output VOUTM and the calibration signal CALIB and provide a logic output signal to the monoshot circuit 334. The monoshot circuit 334 includes circuitry (see, e.g., FIG. 4) configured to provide complementary pulsed signals at the respective outputs 336 and 338, which are inverted versions of each other. The delay circuit 340 is configured to delay the pulse signal at the output 338 to provide a delayed version thereof at the output 314. For example, the falling edge of the control signal at the output 314 is delayed relative to the rising edge of the control signal at the output 312. In other examples, the offset control circuit 300 can be configured to implement other temporal relationships among the offset control signals at the outputs 308, 310, 312, and 314, which may depend on application requirements and/or the configuration of the offset calibration circuit (e.g., the offset calibration circuit 160, 260).

FIG. 4 is a diagram of an example monoshot circuit 400 that can be implemented as the monoshot circuit 324 and 334 in the offset control circuit 300 of FIG. 3. The monoshot circuit 400 includes an input 402 and outputs 404 and 406. The monoshot circuit 400 is configured to provide signal pulses at the outputs 404 and 406 responsive to an input signal received at the input 402, in which the signal pulses at the outputs 404 and 406 are temporally aligned complementary versions of each other.

In the example of FIG. 4, the monoshot circuit 400 includes an inverter 408 having an input and an output, in which the input is coupled to the input 402. An AND gate 410 has a pair of inputs 412 and 414 and a pair of outputs, in which one of the inputs is coupled to the input 402 and the outputs are coupled to the respective outputs 404 and 406. A delay element (e.g., one or more inverters) 416 is coupled between the output of the inverter 408 and the input 414 of the AND gate 410. The delay element 416 is configured to provide an amount of delay to define the width of the pulse signals at the outputs 404 and 406.

FIG. 5 depicts an example delay circuit 500 that can be implemented as the delay blocks 330 and 340 and/or in the monoshot circuits 324 and 334 in the offset control circuit 300 of FIG. 3. The delay circuit 500 includes an input 502 and an output 504 and a number of inverters 506 coupled in series between the input 502 and the output 504. The number of inverters 506 defines the amount of delay that is implemented by the delay circuit 500. The delay circuit is configured to delay a signal received at the input 502 and provide an output signal at the output 504 as a delayed version of the input signal based on the number of inverters 506.

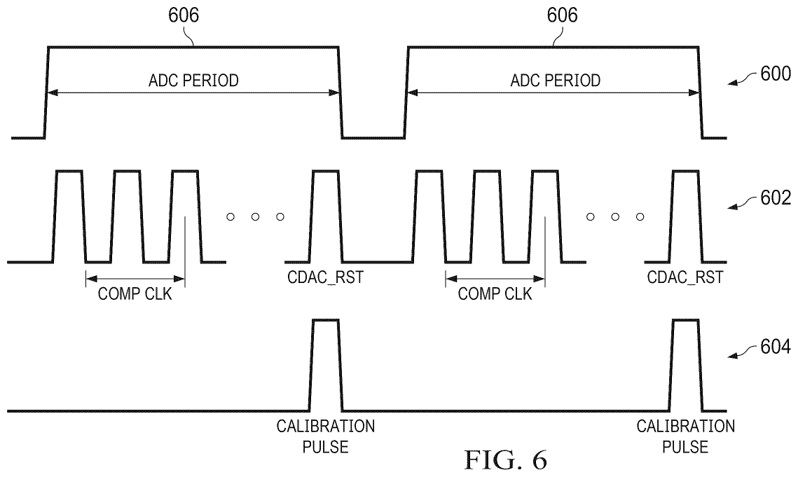

FIG. 6 is a signal diagram 600 depicting examples of timing signals for various parts of an ADC circuit (e.g., the ADC circuit 100, 200, 1402, and the counter circuit 316). The signal diagram 600 includes a comparator clock signal 602 (e.g., CLK signal received at clock inputs 210 and 318 of FIGS. 2 and 3) and a calibration pulse signal 604 (e.g., CALIB signal received at inputs 266 and 306 of FIGS. 2 and 3). In the example of FIG. 6, a number of clock pulses define each ADC period 606, and the calibration pulse can be asserted (e.g., a logic high) once per ADC period. For example, the counter circuit 316 is configured to count the number of pulses each period and, responsive to reaching a count value (e.g., set by the REF_COUNT value), the counter can provide the calibration pulse signal. In this way, the offset correction circuit can implement the offset correction described herein as a background process, which is activated periodically responsive to the calibration pulse signal 604.

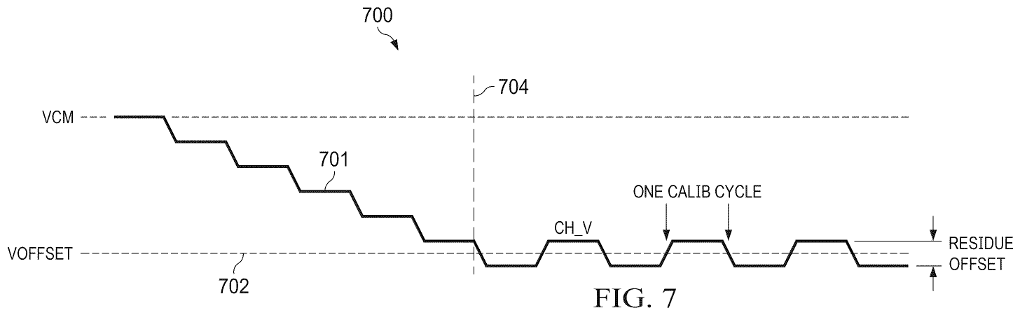

FIG. 7 is a signal diagram 700 depicting an example of convergence for an offset signal 701 (e.g., the signal provided at the offset input 148 of the comparator circuit 136), which can be provided by an offset correction circuit (e.g., the offset correction circuit 156, 204). As shown in the example of FIG. 7, the offset signal 701 starts at the common mode voltage VCM and over series of calibration cycles reduces down to a calibrated offset voltage 702 at a time 704 where it remains until reinitialized, or circuit conditions change necessitating a further change to the offset voltage. The step size for the convergence of the offset signal 701 is based on the magnitude of charge (e.g., sourcing and sinking from the current sources 288 and 290), the size of the capacitor C2, as well as the parasitic capacitances associated with the switches 280, 282, 284, and 286.

FIG. 8A includes signal diagrams 800 and 801 depicting examples of control signals 802, 804, 806, and 808, which can be provided by an offset control circuit (e.g., offset control circuit 158, 258 or 300) to the offset calibration circuit (e.g., offset calibration circuit 160, 260). While the concepts in the signal diagrams 800 and 801 of FIG. 8A are equally applicable to the other example circuitry described herein, the signal diagrams of FIG. 8A are described with reference to the ADC circuit 200 of FIG. 2 and the offset calibration circuit of FIG. 8B. FIG. 8B depicts an example circuit 850 for part of offset calibration circuit 260, in which the switch 280 is shown as including parallel n-channel and p-channel transistors 852 and 854 and the switch 282 is shown as including parallel n-channel and p-channel transistors 856 and 858. The offset control signals (e.g., provided by the offset control circuit 258) thus include complementary signals to each of the switches, shown as PU, P̅U̅_̅Z̅ applied to the switch 280 and PU_Z and P̅U̅ to the switch 282. FIG. 8B also illustrates some parasitic capacitors C3, C4, and C5 associated with the respective switches 280 and 282.

As an example, the control signals 802 and 804 are provided to the control inputs of the switches 282 and 280, and the control signals 806 and 808 are provided to the control inputs of the switches 284 and 286. The control signals 802, 804, 806, and 808 can be supplied to different control inputs in other examples.

During operation of the offset calibration circuit 260, 850 parasitic capacitances associated with the pull-up switches 280 and 282 (e.g., parasitic capacitances between the common node terminal 292 and the offset output 278 and between the common node terminal 292 and the output 281 of the buffer 279) can introduce unwanted charge to the offset output 278. Similarly, parasitic capacitances associated with the pull-down switches 284 and 286 (e.g., parasitic capacitances between the common node terminal 294 and the offset output 278 and between the common node terminal 292 and the output 281 of the buffer 279) can introduce unwanted charge to the offset output 278. The amount of charge that can be introduced can depend on the construction of the switches 280, 282, 284, and 286. As a result of the unwanted charge and based on how offset control signals activate and deactivate the switches could affect loop stability and, if not accounted for, the offset calibration circuit 260 might be unable to achieve the convergence of the offset signal VCH, such as shown in FIG. 7. Accordingly, as described herein, the offset control circuit 258 is configured to provide offset control signals to control relative timing of rising or falling edges of the signals at the outputs 268 and 270 (e.g., provided to the pull-up switches 280 and 282) as well as control relative timing of rising or falling edges of the signals at the outputs 272 and 274 (e.g., provided to the pull-down switches 284 and 286).

Each of the signal diagrams 800 and 801 provides a respective signal timing scheme that includes a pre-calibration time window 810, a calibration time window 812, and a post-calibration time window 814. As an example, in the signal diagram 800, the signal 802 is the PU_Z and the signal 804 is the PU signal shown in FIG. 2. When a signal edge falls, it causes net negative charge spike on the node terminal 292 or 294 based on parasitic capacitance connection and, when a signal edge rises, it causes net positive charge spike. First, during the pre-calibration time window 810, the signal 802 starts to fall, disconnecting pull-up switch 282 (e.g., NMOS transistor 856 on the output side of buffer 279), the switch 280 (e.g., PMOS transistor 854 on the V_CH side of the buffer) is now connected, making the switches 282 and 280 partially connected (or overlapping). After some delay, 804 begins to rise, disconnecting buffer side PMOS 858 and the switch 282 completely, and connecting V_CH side NMOS 852 and the switch 280 completely. During the small overlap time, when the signal 802 started to fall, but the signal 804 has not started to rise, the pull-up switch 282 at the output side of the buffer 279 is still partially connected, compensating for partial negative charge to common node terminal 292 given by fall of the signal 802 due to parasitic capacitances associated with the switch 282 (see, e.g., region 816 during the pre-calibration time window 810 of FIG. 8A). The rest of the charge due to the fall of the signal 802 and the rise of the signal 804 to common node terminal 292 is accumulated on V_CH side (see, e.g., region 818 during the pre-calibration time window 810 of FIG. 8A) resulting in net positive charge on V_CH at the output 278 and net negative charge at the buffer output 281.

Similarly, during the post-calibration time window 814, the signal 802 starts to rise, disconnecting the PMOS transistor 854 of the switch 280, the NMOS transistor 856 of the switch 282 is connected now, making the switches 282 and 280 partially connected. After some delay, the signal 804 begins to fall, disconnecting the NMOS transistor 852 of the switch 280 completely, and connecting the PMOS transistor 858 of the switch 282 completely. During the small overlap time, when the signal 802 started to rise, but the signal 804 has not started to fall, the switch 280 is still partially connected, compensating for partial positive charge to common node terminal 292 given by rise of the signal 802 due to parasitic capacitance associated with the switch 280 (see, e.g., region 820 during the post-calibration time window 814 of FIG. 8A). The rest of the charge due to the rise of the signal 802 and fall of the signal 804 to common node terminal 292 is accumulated on the output 281 of the buffer (see, e.g., region 822 during the post-calibration time window 814 of FIG. 8A) resulting in net negative charge on buffer output 281 and net positive charge on the output 278. The buffer side charge is provided by the buffer 279, making it insignificant to the rest of the operation.

In the signal diagram 801, the falling edge of the signal 806 is delayed with respect to the rising edge of the signal 808, which is opposite of what is being done in control signal schemes of the signal diagram 800. This results in net negative charge on V_CH side (at the output 278) and net positive charge on buffer side (at the output 281 of the buffer) at the end of both pre- and post-calibration time windows 810 and 814. As described herein, the offset control circuit 258 is configured to control the switch control signals so that the clock feedthrough effect is always in the same direction as intended by the charge pump current. The clock feedthrough effect refers to when a signal rises or falls, the signal introduces positive or negative charge spike on some other net due to parasitic capacitors.

Therefore, the offset control circuit 258 provides an improved clocking scheme for the offset calibration circuit 260 that can implement finer offset calibration (e.g., smaller steps in the convergence of VCH during calibration). In addition to improved performance, the approach also enables a reduction in the area of the offset correction circuit 204 (e.g., up to at least 50% area reduction) compared to existing approaches. Also, or as an alternative, the approach also enables a smaller capacitor C2 to be used in the offset calibration circuit 260 compared to many existing approaches.

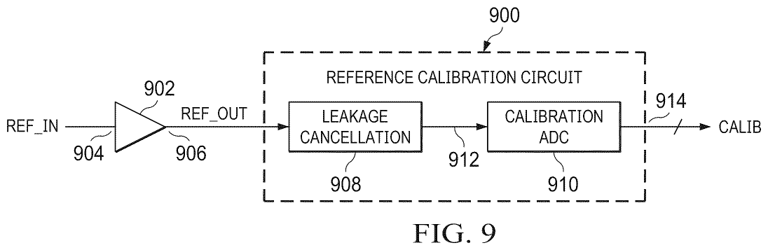

FIG. 9 depicts an example of part of an ADC circuit including a reference calibration circuit 900 and a reference buffer 902, in which the reference calibration circuit 900 provides a useful example of the reference calibration circuit 108 of FIG. 1. The reference buffer 902 can be implemented as the reference buffer 102 of FIG. 1. Accordingly, the description of FIG. 9 can refer to certain aspects of FIG. 1. The reference buffer 902 includes one or more reference inputs 904 and one or more reference outputs 906. The reference buffer 902 is configured to provide a reference output signal (e.g., a reference voltage REF_OUT) at the reference output 906 for the ADC circuit. In some examples, the reference output signal REF_OUT is sensed by circuitry that can exhibit leakage. Such leakage can result in leakage error (e.g., inaccurate reference sensing) when sensing the reference output signal REF_OUT. Accordingly, the reference calibration circuit 900 is configured to compensate for the leakage error.

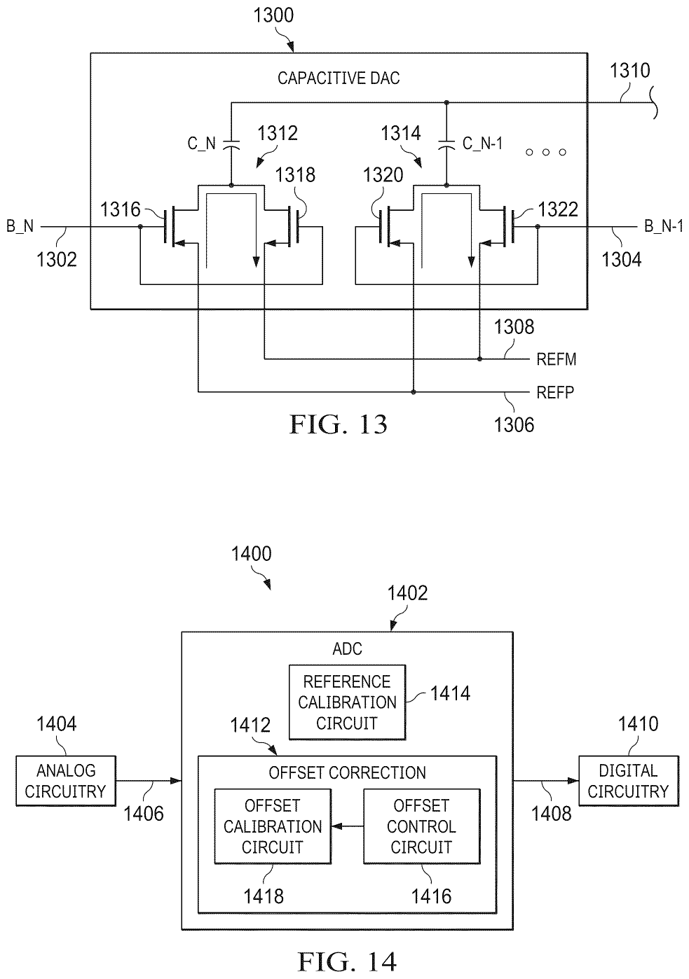

The reference calibration circuit 900 includes a leakage cancellation circuit 908 and a calibration ADC 910. The leakage cancellation circuit 908 includes an input and an output 912, in which the input of the leakage cancellation circuit is coupled to the reference output 906. The output 912 of the leakage cancellation circuit 908 is coupled to an input of the calibration ADC 910. The leakage cancellation circuit 908 is configured simulate the leakage error of reference sensing circuitry (e.g., switches, such as transistors of a DAC—see FIG. 13) and adjust the reference output signal REF_OUT to provide an adjusted reference signal at the output 912 based on the simulated leakage error. The calibration ADC 910 is configured to provide calibration data CALIB at a converter output 914 based on the adjusted reference signal. For example, the adjusted reference signal is an analog signal, and the calibration ADC 910 is configured to convert the analog adjusted reference signal to a respective digital representation thereof, namely the calibration data CALIB data. The calibration data CALIB can be used (e.g., by the digital engine 114) to implement digital gain correction for the ADC circuit to calibrate out (e.g., reduce) the leakage errors. The leakage errors can be fixed or vary based on the temperature of the ADC circuit (or at least the portions sensing the reference output signal REF_OUT).

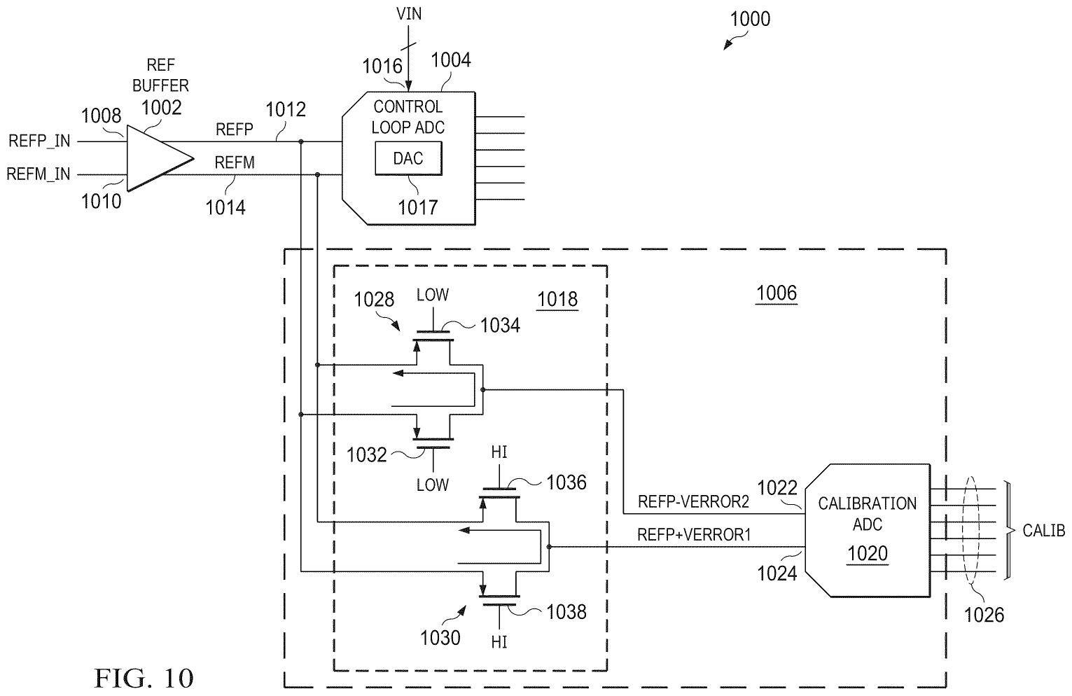

FIG. 10 depicts an example of part of an ADC circuit 1000, which includes a reference buffer 1002, a control loop ADC 1004, and a reference calibration circuit 1006. In the example of FIG. 10, the reference buffer 1002 and the reference calibration circuit 1006 are differential circuitry. The reference buffer 1002 thus includes a pair of inputs 1008 and 1010 to receive input signals REFP_IN and REFM_IN and a pair of outputs 1012 and 1014 to provide reference signals, shown as REFP and REFM, respectively. The control loop ADC 1004 includes first and a second analog inputs, in which the first analog input is coupled to the first reference output 1012, and the second analog input is coupled to the second reference output 1014. The control loop ADC 1004 1004 also has one or more inputs 1016 to receive one or more analog input signals (e.g., a differential input signal) VIN. In an example, the control loop ADC 1004 can be implemented by circuitry of FIG. 1, including the analog front end circuit 134, the comparator 136, the register 152, and the DAC 154. Other ADC configurations can be used to implement the control loop ADC 1004 in other examples.

The reference calibration circuit 1006 includes a leakage cancellation circuit 1018 (e.g., leakage cancellation circuit 908) and a calibration ADC 1020 (e.g., calibration ADC 910). The calibration ADC 1020 has a pair of calibration inputs 1022 and 1024 and a plurality of outputs 1026 (e.g., defining a multi-bit calibration output, such as representing the CALIB signal at 914 of FIG. 9). The leakage cancellation circuit 1018 includes first and second leakage cancellation circuits 1028 and 1030. The first leakage cancellation circuit 1028 is coupled between the reference outputs 1012 and 1014 and the calibration input 1022, and the second leakage cancellation circuit 1030 is coupled between the reference outputs 1012 and 1014 and the other calibration input 1024.

The first leakage cancellation circuit 1028 includes a first switch (e.g., transistor) 1032 coupled between the first reference output 1012 and the calibration input 1022 and a second switch 1034 coupled between the second reference output 1014 and the calibration input 1022. Similarly, the second leakage cancellation circuit 1030 includes switches (e.g., transistors) 1036 and 1038, in which the switch 1036 is coupled between the reference output 1014 and the calibration input 1024, and the other switch 1038 is coupled between the reference output 1012 and the calibration input 1024. In the example of FIG. 10, the switch 1032 is a p-channel FET having a source coupled to the reference output 1012, a drain coupled to the calibration input 1022, and a gate coupled to a first bit terminal 1040. Also, in the example of FIG. 10, the other switch 1034 is an n-channel FET having a source coupled to the reference output 1014, a drain coupled to the calibration input 1022, and a gate coupled to the same bit terminal (e.g., shown as LOW) as the other FET (switch 1032) in the respective leakage cancellation circuit 1028. The switch 1036 is a n-channel FET having a source coupled to the reference output 1014, a drain coupled to the calibration input 1024, and a gate coupled to a second bit terminal 1042. The other switch 1038 is a p-channel FET having a source coupled to the reference output 1012, a drain coupled to the calibration input 1024, and a gate coupled to the same bit terminal (e.g., shown as HI) as the other FET (switch 1036) in the respective leakage cancellation circuit 1030.

In an example, one of the bit terminals 1040, 1042 is coupled to a logic low and another of the bit terminals 1040, 1042 is coupled to a logic high. In this way, each of the leakage cancellation circuits 1028 and 1030 is configured to provide a respective output signal representative of one of the reference signals REFP, REFM adjusted based on respective leakage error (also referred to as respective adjusted reference signals). For example, the leakage cancellation circuit 1028 is configured to provide an adjusted reference signal approximating REFP−V_ERROR2, where V_ERROR2 is representative of leakage through the transistor (an n-channel FET) 1034 responsive to a logic low signal at the bit terminal 1040. The leakage cancellation circuit 1030 is configured to provide an adjusted reference signal approximating REFP+V_ERROR1, where V_ERROR1 is representative of leakage through the transistor (a p-channel FET) 1038 responsive to a logic high signal at the bit terminal 1042. The calibration ADC 1020 is configured to provide calibration data CALIB at the multi-bit converter output 1026 based on the adjusted reference signal. Advantageously, the leakage errors can be automatically calibrated out (e.g., reduced) by the calibration ADC.

FIG. 11 depicts an example reference buffer circuit 1100. The reference buffer circuit 1100 provides a useful example of the reference buffers 902 and 1002 of FIGS. 9 and 10, respectively. Accordingly, the description of FIG. 11 can also refer to certain aspects of FIGS. 9 and/or 10. In the example of FIG. 11, the reference buffer circuit 1100 includes inputs 1102 and 1104 (e.g., inputs 904, 1008, and 1010) and outputs 1106 and 1108 (e.g., outputs 906, 1012, and 1014). The reference buffer circuit 1100 includes a divider circuit of resistors R1, R2, and R3 coupled in series between first and second voltage terminals, shown as a ground terminal and VREF (e.g., a DC voltage).

The reference buffer circuit 1100 also includes operational amplifiers (op-amps) 1110 and 1112. The op-amp 1110 includes an inverting input coupled to the input 1102, a non-inverting input coupled to the output 1106, and an output 1114. The op-amp 1112 includes an inverting input coupled to the input 1104, a non-inverting input coupled to the output 1108, and an output 1116. The reference buffer circuit 1100 also includes transistors 1118 and 1120, in which the transistor 1118 is coupled between a voltage supply terminal (e.g., VDD) 1122 and the output 1106, and the transistor 1120 is coupled between the output 1108 and the ground terminal. For example, the transistor 1118 is a p-channel FET having a drain coupled to the output 1106, a source coupled to the voltage supply terminal 1122 (e.g., at a voltage shown as VDD), and a gate coupled to the output 1114 of the op-amp 1110. The other transistor 1120 is an n-channel FET having a drain coupled to the output 1108, a source coupled to the ground terminal, and a gate coupled to the output 1116 of the op-amp 1112. The op-amp 1110 is configured to control the transistor 1118 based on the input voltage REFP_IN and the voltage REFP to set the reference output voltage REFP. Similarly, the op-amp 1112 is configured to control the transistor 1120 based on the input voltage REFM_IN and the voltage REFM to set the reference output voltage REFM.

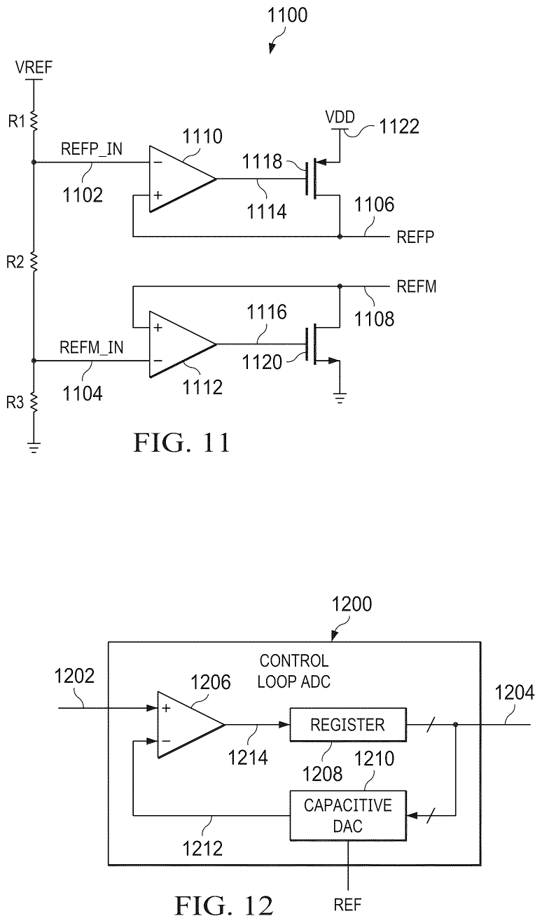

FIG. 12 depicts an example control loop ADC 1200 having one or more inputs 1202 and an output 1204 (e.g., a multi-bit output). The control loop ADC 1200 is an example of the control loop ADC 1004 of FIG. 10. Accordingly, the description of FIG. 12 can also refer to certain aspects of FIG. 10. In the example of FIG. 12, the control loop ADC 1200 includes a comparator (e.g., comparator circuit 136, 202) 1206, a register (e.g., register 152) 1208, and a capacitive DAC (e.g., DAC 154) 1210. The op-amp includes a non-inverting input coupled to the one or more inputs 1202, an inverting input coupled to an output 1212 of the capacitive DAC 1210, and an output 1214 coupled to an input of the register 1208. The comparator 1206 can be configured to provide a comparator output signal (e.g., a digital signal) that defines a bit stream that varies between logic low and logic high voltage values based on the one or more input signals at 1202 and an analog feedback signal provided by the capacitive DAC 1210 at the output 1212. The register can store samples of the output signal at 1214 to provide a multi-bit digital signal at the output 1204 representative of the one or more input signals received at the one or more inputs 1202. The capacitive DAC 1210 can have one or more inputs coupled to the output 1204 to receive the multi-bit digital signal. The capacitive DAC 1210 can be configured to convert the multi-bit digital signal at the output 1204 to a respective analog signal provided at the output 1212 of the capacitive DAC 1210, which is provided as the analog feedback signal to the comparator 1206.

FIG. 13 depicts an example capacitive DAC 1300, which can be implemented in a control loop analog-to-digital converter. The capacitive DAC 1300 provides a useful example of the DAC 154, the DAC 1017, and the capacitive DAC 1210. Accordingly, the description of FIG. 13 can also refer to certain aspects of FIGS. 1, 10 and 12. The capacitive DAC 1300 includes a number (N) of digital inputs 1302 and 1304, reference inputs 1306 and 1308, where N is representative of the number of digital inputs (e.g., N>=2), and an output 1310. In the example of FIG. 13, two such digital inputs 1302 and 1304 are shown as receiving digital input signals B_N and B_N−1, respectively, which signals can be provided by an ADC (e.g., the control loop ADC 1004, 1200). There can be any number N of digital inputs (as indicated by the ellipsis) in other examples. The reference inputs 1306 and 1308 receive respective reference signals REFM and REFP, which can be provided by a reference buffer (e.g., reference buffer 102, 902, 1002).

The capacitive DAC 1300 includes a reference sensing circuit 1312 and 1314 associated with each of the digital inputs 1302 and 1304. The reference sensing circuit 1312 is coupled in series with a capacitor C_N between the output 1310 and the reference inputs 1306 and 1308. The reference sensing circuit 1314 is coupled in series with a capacitor C_N−1 between the output 1310 and the reference inputs 1306 and 1308.

The reference sensing circuit 1312 includes a first switch (e.g., transistor) 1316 coupled between the capacitor C_N and the reference input 1306 and a second switch (e.g., transistor) 1318 coupled between the capacitor C_N and the reference input 1308. Similarly, the other reference sensing circuit 1314 includes switches (e.g., transistors) 1320 and 1322, in which the switch 1320 is coupled between the capacitor C_N−1 and the reference input 1306, and the other switch 1322 is coupled between the capacitor C_N−1 and the reference input 1308. In the example of FIG. 13, the switch 1316 is a p-channel FET and the switch 1318 is an n-channel FET. The p-channel FET (switch 1316) has a source coupled to the reference input 1306, a drain coupled to capacitor C_N, and a gate coupled to the digital input 1302. The n-channel FET (switch 1318) has a source coupled to the reference input 1308, a drain coupled to capacitor C_N (and to the drain of the FET 1316), and a gate coupled to the digital input 1302.

Each other reference sensing circuit 1314 in the capacitive DAC 1300 can be similarly configured for a respective digital input 1304. For example, the switch 1320 is a p-channel FET having a source coupled to the reference input 1306, a drain coupled to capacitor C_N−1, and a gate coupled to the digital input 1304. The switch 1322 is an n-channel FET having a source coupled to the reference input 1308, a drain coupled to capacitor C_N−1 (and to the drain of the FET 1320), and a gate coupled to the digital input 1304. In this way, the source of each p-channel FET can receive the reference signal REFP, and the source of each n-channel FET can receive the reference signal REFM. As described herein, each of the reference sensing circuits 1312 and 1314 can introduce an error signal (e.g., a voltage drop across the respective non-activated switch of the reference sensing circuits) due to leakage that depends on the value of the signal at the digital inputs 1302 and 1304. For example, responsive to a low digital value at an input (e.g., digital input 1302 and/or 1304) the leakage error results from leakage current through the n-channel FET (e.g., FET 1318 and/or 1322). Conversely, responsive to a high digital value at an input (e.g., digital input 1302 and/or 1304) the leakage error results from leakage current through the p-channel FET (e.g., FET 1316 and/or 1320). The amount of leakage error for each reference sensing circuit 1312 and 1314 is based on (e.g., functionally related to) the relative areas of the respective p-channel and n-channel FETs and through which FET the leakage current propagates. Each reference sensing circuit 1312 and 1314 of the capacitive DAC 1300 can be configured so the relative areas of the respective p-channel and n-channel FETs are the same. The leakage error is provided through the respective capacitors to the output 1310.

In order to compensate for the leakage error, the reference calibration circuit 108, 900, 1006 is configured to simulate the leakage error introduced by the capacitive DAC of the ADC to enable a gain correction of the ADC. In the example of FIG. 10, each of the leakage cancellation circuits 1028, 1030 is configured to simulate the leakage error. For example, each of the leakage cancellation circuits 1028, 1030 includes an instance of p-channel and n-channel FETs configured to have the same size ratio (e.g., a width to length ratio) as the p-channel and n-channel FETs in the capacitive DAC. As a result, the leakage error produced by each of the leakage cancellation circuits 1028 and 1030 can track (e.g., approximate or be equal to) the leakage error of the FETs in the reference sensing circuits 1312 and 1314. In view of the foregoing, because the value of the reference voltage (e.g., REFM and/or REFP) sensed by the reference calibration circuit 108, 900, 1006 tracks the values seen by the capacitive DAC 1300, the ADC accuracy can be relatively insensitive to switch leakage. Because the capacitive leakage error can be effectively calibrated out (or eliminated by the reference calibration circuit), the switches (e.g., FETs 1316, 1318, 1320, 1322) in the capacitive DAC 1300 can be designed to have a lower on resistance compared to many existing approaches. As a result, the ADC 100 can better tolerate leakages which enables an increase in the overall ADC sampling and conversion speed.

FIG. 14 depicts an example of a system 1400 that includes an ADC circuit 1402. The system 1400 can be implemented in a variety of applications, including automotive, data centers, and signal processing applications, in which input analog signals are converted to respective digital signals. The system 1400 includes analog circuitry 1404 that provides an analog signal(s) to an input(s) 1406 of the ADC circuit 1402. The ADC circuit 1402 can be implemented by the ADC circuit 100, 200, or 1200 described herein that is configured to convert the analog signal(s) to a respective digital output signal at an output 1408 of the ADC circuit 1402. The digital output signal at the output 1408 of the ADC circuit 1402 can be a data signal having a number of one or more bits according to the configuration of the ADC circuit 1402, which is provided to digital circuitry 1410 for processing. As described herein, the ADC circuit 1402 includes an offset correction circuit 1412 (e.g., offset correction circuit 156, 204) and/or a reference calibration circuit 1414 (e.g., reference calibration circuit 108, 900, 1006). The offset correction circuit 1412 includes an offset control circuit 1416 (e.g., offset control circuit 158, 258, 300) and an offset calibration circuit 1418 (e.g., offset calibration circuit 160, 260). As described herein, the offset control circuit 1416 is configured to provide one or more calibration control signals to control the timing of the offset calibration circuit 160 to ensure offset loop convergence and efficient operation of a comparator (e.g., comparator 136, 202, 1206) of the ADC circuit 1402. Also, as described herein, the reference calibration circuit 1414 is configured to simulate leakage error of a DAC circuit (e.g., DAC 154, 1017, 1210, 1300) of the ADC circuit and provide calibration data based on the simulated leakage error. The calibration data thus can effectively calibrate out the leakage errors, which can enable faster switches (e.g., transistors) and an overall increase in speed and an increased dynamic range for the ADC circuit 1402.

In this description, numerical designations “first”, “second”, etc. are not necessarily consistent with the same designations in the claims herein. Additionally, the term “couple” or variants thereof may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not alter the functional relationship between device A and device B, so device B is controlled by device A via the control signal generated by device A. In this description, the term “based on” means based at least in part on.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means within +/−10 percent of the stated value, or, if the value is zero, a reasonable range of values around zero. Modifications are possible in the described embodiments, and other embodiments are possible, within the scope of the claims.

What is claimed is:

1. A circuit comprising:
a comparator circuit including an input, a first output, and a second output;
an offset control circuit including a first input, a second input, a first output, and a second output, in which the first input of the offset control circuit is coupled to the first output of the comparator circuit, the second input of the offset control circuit is coupled to the second output of the comparator circuit, and the offset control circuit comprises:
a first delay circuit coupled between the first input and the first output of the offset control circuit; and
a second delay circuit coupled between the input and the second output of the offset control circuit;
an offset calibration circuit having a first input and a second input, in which the first input of the offset calibration circuit is coupled to the first output of the offset control circuit, the second input of the offset calibration circuit is coupled to the second output of the offset control circuit; and
a capacitor coupled to the input of the comparator circuit.

2. The circuit of claim 1, wherein the offset calibration circuit comprises:
a buffer having an input and an output, in which the input of the buffer is coupled to the input of the comparator circuit;
a first switch having a first current terminal and a second current terminal, in which the first current terminal of the first switch is coupled to the input of the buffer;
a second switch having a first current terminal, a second current terminal, and a control terminal, in which the first current terminal of the second switch is coupled to the output of the buffer, and the second current terminal of the second switch is coupled to the second current terminal of the first switch;
a third switch having a first current terminal and a second current terminal, in which the first current terminal of the third switch is coupled to the input of the buffer; and
a fourth switch having a first current terminal and a second current terminal, in which the first current terminal of the fourth switch is coupled to the output of the buffer, and the second current terminal of the fourth switch is coupled to the second current terminal of the third switch.

3. The circuit of claim 2, wherein the first delay circuit has an input and an output, the second delay circuit has an input and an output, and the offset control circuit comprises:
a first monoshot circuit having an input, a first output, and a second output, in which the input of the first monoshot circuit is coupled to the first output of the comparator circuit, the first output of the first monoshot circuit is coupled to the input of the first delay circuit, the output of the first delay circuit is coupled to the control terminal of the first switch, and the second output of the first monoshot circuit is coupled to the control terminal of the second switch; and
a second monoshot circuit having an input, a first output, and a second output, in which the input of the second monoshot circuit is coupled to the second output of the comparator circuit, the first output of the second monoshot circuit is coupled to the input of the second delay circuit, the second output of the second monoshot circuit is coupled to the control terminal of the fourth switch, and the first output of the second monoshot circuit is coupled to the control terminal of the third switch.

4. The circuit of claim 3, wherein the offset control circuit further comprises:
a first logic configured to provide a first logic signal at the input of the first monoshot circuit responsive to a first comparator signal at the first output of the comparator circuit and a calibration timing signal; and
a second logic configured to provide a second logic signal at the input of the second monoshot circuit responsive to a second comparator signal at the second output of the comparator circuit and the calibration timing signal.

5. The circuit of claim 4, wherein:
the first monoshot circuit is configured to provide first and second pulse signals at the first and second outputs of the first monoshot circuit, respectively, responsive to the first logic signal, in which the second pulse signal is a complementary version of the first pulse signal,
the first delay circuit is configured to delay the first pulse signal relative to the second pulse signal and provide a delayed first pulse signal at the output of the first delay circuit,
the second monoshot circuit is configured to provide third and fourth pulse signals at the first and second outputs of the second monoshot circuit, respectively, responsive to the second logic signal, in which the fourth pulse signal is a complementary version of the third pulse signal, and
the second delay circuit is configured to delay the fourth pulse signal relative to the third pulse signal and provide a delayed fourth pulse signal at the output of the second delay circuit.

6. The circuit of claim 5, wherein the offset calibration circuit is configured to provide an offset signal at the input of the comparator circuit responsive to the delayed first pulse signal, the second pulse signal, the third pulse signal, and the delayed fourth pulse signal.

7. The circuit of claim 5, wherein the first delay circuit is configured to delay the first pulse signal so a falling edge of the second pulse signal occurs before a rising edge of the delayed first pulse signal, and
wherein the second delay circuit is configured to delay the fourth pulse signal so a rising edge of the third pulse signal occurs before a falling edge of the delayed fourth pulse signal.

8. The circuit of claim 2, wherein the offset calibration circuit further comprises:
a first current source coupled to the second current terminal of the second switch; and
a second current source coupled to the second current terminal of the third switch.

9. The circuit of claim 8, wherein the input of the comparator circuit is a first input, the comparator circuit further has a second input and a third input, the comparator circuit further comprises:
a first transistor having a first current terminal, a second current terminal, and a control terminal, in which the control terminal of the first transistor is coupled to the second input of the comparator circuit;
a second transistor having a first current terminal, a second current terminal, and a control terminal, in which the control terminal of the second transistor is coupled to the third input of the comparator circuit; and
a strong-arm latch circuit coupled to first current terminal of the first transistor and the first current terminal of the second transistor,
wherein the offset calibration circuit further comprises:
a third transistor having a first current terminal, a second current terminal, and a control terminal, in which the first current terminal of the third transistor is coupled to the first current terminal of the second transistor, the second current terminal of the third transistor is coupled to the second current terminal of the second transistor, and the control terminal of the third transistor is coupled to the first input of the comparator circuit.

10. The circuit of claim 1, further comprising:
a buffer including an output;
a calibration analog-to-digital converter including an input and an output; and
a leakage cancellation circuit coupled between the output of the buffer and the input of the calibration analog-to-digital converter, in which the leakage cancellation circuit is configured to simulate leakage error of a digital-to-analog converter circuit and adjust a reference signal at the output of the buffer, and the calibration analog-to-digital converter is configured to provide calibration data at the output of the calibration analog-to-digital converter based on the adjusted reference signal.

11. The circuit of claim 10, wherein the input of the comparator circuit is a first input, the comparator circuit further has a second input and a third input, and the circuit further comprises:
an analog front end circuit including a first input, a second input, a third input, a first output, and a second output, in which the third input of the analog front end circuit is coupled to the output of the buffer, the first output of the analog front end circuit is coupled to the second input of the comparator circuit, the second output of the analog front end circuit is coupled to the third input of the comparator circuit, and the analog front end circuit is configured to provide an analog signal at the second and third inputs of the comparator circuit based on an input voltage at the first and second inputs of the analog front end circuit and the reference signal at the third input of the analog front end circuit.

12. A circuit, comprising:
a buffer including an output;
an analog-to-digital converter including an input and an output; and
a leakage cancellation circuit coupled between the output of the buffer and the input of the analog-to-digital converter, in which the leakage cancellation circuit is configured to simulate leakage error of a digital-to-analog converter circuit, and the analog-to-digital converter is configured to provide calibration data at the output of the analog-to-digital converter based on the simulated leakage error.

13. The circuit of claim 12, wherein:
the output of the buffer is a first output, the buffer further includes a second output,
the input of the analog-to-digital converter is a first input, the analog-to-digital converter further includes a second input, and
the leakage cancellation circuit includes a first leakage cancellation circuit and a second leakage cancellation circuit, in which the first leakage cancellation circuit is coupled between the first output of the buffer and the first input of the analog-to-digital converter, and the second leakage cancellation circuit is coupled between the second output of the buffer and the second input of the analog-to-digital converter.

14. The circuit of claim 13,
wherein the first leakage cancellation circuit comprises:
a first switch coupled between the first output of the buffer and the first input of the analog-to-digital converter; and
a second switch coupled between the second output of the buffer and the first input of the analog-to-digital converter, and
wherein the second leakage cancellation circuit comprises:
a third switch coupled between the second output of the buffer and the second input of the analog-to-digital converter; and
a fourth switch coupled between the first output of the buffer and the second input of the analog-to-digital converter.

15. The circuit of claim 14,
wherein the first switch is a p-channel field effect transistor having a source coupled to the first output of the buffer and a drain coupled to the first input of the analog-to-digital converter, and
wherein the second switch is an n-channel field effect transistor having a source coupled to the second output of the buffer and a drain coupled to the first input of the analog-to-digital converter.

16. The circuit of claim 13, wherein the analog-to-digital converter is a first analog-to-digital converter, the circuit further comprising:
a second analog-to-digital converter having a first analog input and a second analog input, in which the first analog input is coupled to the first output of the buffer, and the second analog input is coupled to the second output of the buffer.

17. The circuit of claim 16, wherein the second analog-to-digital converter has a plurality of digital outputs and comprises the digital-to-analog converter circuit, and the digital-to-analog converter circuit is a capacitive digital-to-analog converter circuit comprising:
a plurality of digital inputs, each coupled to a respective one of the plurality of digital outputs of the second analog-to-digital converter,
an analog output coupled to one of the first or second analog inputs of the second analog-to-digital converter;
a first switch having a first current terminal, a second current terminal, and a control terminal, in which the second current terminal of the first switch is coupled to the first output of the buffer, and the control terminal of the first switch is coupled to a first digital input of the plurality of digital inputs;
a second switch having a first current terminal, a second current terminal, and a control terminal, in which the first current terminal of the second switch is coupled to the first current terminal of the first switch, the second current terminal of the second switch is coupled to the second output of the buffer, and the control terminal of the second switch is coupled to the first digital input of the plurality of digital inputs; and
a capacitor coupled between the first current terminal of the first switch and the analog output.

18. The circuit of claim 12, wherein the buffer is configured to provide a reference signal, the leakage cancellation circuit is configured to provide an adjusted reference signal based on the reference signal and the simulated leakage, the analog-to-digital converter is configured to provide the calibration data at the output of the analog-to-digital converter based on the adjusted reference signal, and the circuit further comprises:
a comparator circuit configured to provide first and second comparator output signals based on first and second input signals at respective first and second inputs of the comparator circuit and an offset signal at a third input of the comparator circuit;
a capacitor coupled to the third input of the comparator circuit;
an offset correction circuit, the offset correction circuit comprising:
an offset control circuit configured to provide calibration control signals responsive to the first and second comparator output signals and a calibration timing signal; and
an offset calibration circuit including a charge pump configured to provide the offset signal responsive to the calibration control signals, in which the calibration control signals are provided to control a net charge on the capacitor during pull-up and pull-down phases of the charge pump.

19. An analog-to-digital converter system, comprising:
a comparator circuit configured to provide first and second comparator output signals based on receiving first and second input signals and an offset signal;
an offset correction circuit, the offset correction circuit comprising:
an offset control circuit configured to provide calibration control signals responsive to the first and second comparator output signals and a calibration timing signal; and
an offset calibration circuit including a charge pump configured to provide the offset signal responsive to the calibration control signals, in which the calibration control signals are provided to control a net charge of the offset signal during pull-up and pull-down phases of the charge pump.

20. The analog-to-digital converter system of claim 19, further comprising:
a reference buffer configured to provide a reference signal;
a leakage cancellation circuit configured to simulate a leakage error of a digital-to-analog converter circuit of the analog-to-digital converter system and provide an adjusted reference signal; and
a calibration analog-to-digital converter configured to provide calibration data based on the adjusted reference signal.
